(19) United States
(12) Patent Application Publication
(10) Pub. No.: US 2024/0232491 A1
(43) Pub. Date: Jul. 11, 2024

(54) APPARATUS, SYSTEMS AND METHODS FOR PROGRAMMABLE LOGIC MACROS

(71) Applicant: UNIVERSITY OF FLORIDA RESEARCH FOUNDATION, INCORPORATED, Gainesville, FL (US)

(72) Inventors: Swarup BHUNIA, Gainesville, FL (US); Pravin Dasharth GAIKWAD, Gainesville, FL (US); Jonathan William CRUZ, Gainesville, FL (US); Peyman DEHGHANZADEH, Gainesville, FL (US)

(21) Appl. No.: 18/408,267

(22) Filed: Jan. 9, 2024

Related U.S. Application Data
(60) Provisional application No. 63/479,283, filed on Jan. 10, 2023.

(51) Int. Cl. G06F 30/343

(52) U.S. Cl. CPC G06F 30/343

(57) ABSTRACT

Methods and system are provided for designing a programmable circuitry. The method may generate a cell library with custom multi-input and multi-output configurable logic cells and introduce such in a netlist design. The methods may increase the configuration and diversity of cells to increase the security of the underlying design. The methods may to randomize the interconnects by changing a set of cells used. The methods may integrate any of the steps with electronic design automation (EDA) synthesis tools.

### CROSS-REFERENCE TO RELATED APPLICATIONS

This application claims priority to and the benefit of U.S. Provisional Application Ser. No. 63/479,283, filed Jan. 10, 2023, the contents of which are incorporated by reference herein in its entirety.

### TECHNICAL FIELD

The present disclosure relates to programmable logic design and systems, for example programmable logic macro architecture.

### BACKGROUND

Due to the current horizontal supply chain model of chip fabrication, there is reliance on third party facilities to expedite the manufacturing process and to reduce the manufacturing cost. This dependence on third parties, such as a foundry and assembler, raises questions related to the security of the entire system and raises various challenges related to hardware assurance. For example, hardware and/or circuit design entities may wish to maintain the confidentiality of their Intellectual Property (IP) when sending their designs to third parties for fabrication, etc.

### BRIEF SUMMARY

Various embodiments described herein relate to systems, apparatuses, products, and methods for programmable logic design. In an embodiment, a method for designing a programmable circuitry is provided. The method includes mapping a design of the programmable circuitry into one or more PRogrammable lOgic Macro (PROM) cells, wherein each PROM cell comprises one or more PROM input ports, one or more PROM output ports, a function module, a configuration bit register, and a multiplexer; determining a selector input of the multiplexer using values of one or more configuration bits; storing the one or more configuration bits in the configuration bit register; configuring a function of each PROM cell using the values of the one or more configuration bits; and providing a set of dummy inputs to the one or more PROM input ports, wherein (a) the set of dummy inputs is unknown in a fabricating process of the programmable circuitry and obfuscates the design of the programmable circuitry and (b) the values of the one or more configuration bits determine a function of the corresponding PROM cell performed on PROM inputs and PROM output regardless of the set of dummy inputs.

In various embodiments, one or more data inputs of the multiplexer are electronically coupled to the function module and the multiplexer electronically couples an operation circuitry from the function module to a PROM output port of the one or more PROM output ports using the values of the one or more configuration bits.

In various embodiments, the method may include combining the function module and the multiplexer at a transistor level by using a transistor to perform a common action of the function module and the multiplexer, eliminating a plurality of duplicate transistors between the function module and the multiplexer to reduce an area consumption in the programmable circuitry, and optimizing the area consumption by combining any common actions of the function module and the multiplexer at a transistor level.

In various embodiments, the method may include customizing each PROM cell by varying at least one of a PROM input size, a PROM output size, or the function of the corresponding PROM cell using the one or more configuration bits. In various embodiments, the method may include customizing any PROM inputs and PROM outputs and relationship between the PROM outputs and PROM inputs using the one or more configuration bits, wherein the customization comprises varying any of the PROM input size, PROM output size, and the function of the PROM cell.

In various embodiments, the method may include incorporating the one or more PROM cells in a netlist design of the programmable circuitry. The method may include varying at least one of a number of the one or more PROM input ports, a number of the one or more PROM output ports, the one or more configuration bits, or the set of dummy inputs.

In various embodiments, the method may include randomizing one or more interconnections in the programmable circuitry using at least one of the one or more configuration bits, or the set of dummy inputs.

In various embodiments, the method may include sharing the one or more configuration bits among function modules of the one or more PROM cells. In various embodiments, the method may include sharing the one or more configuration bits among the one or more function modules of a PROM cell of the one or more PROM cells, wherein each PROM cell comprises one or more functions. In various embodiments, the method may include overlapping functions among the function modules of the one or more PROM cells.

In various embodiments, a method is provided to include generating a set of basic functions for a circuit design, generating a set of PRogrammable lOgic Macro (PROM) cells corresponding to the circuit design, configuring each PROM cell to perform a PROM cell function such that the set of PROM cells together perform any function of a circuit that the circuit design represents, mapping the circuit design to one or more PROM cells of the set of PROM cells, and generating configuration bits for each of the one or more PROM cells, wherein the configuration bits program the corresponding PROM cell to perform the corresponding PROM cell function, such that a set of programmed PROM cells perform a specific function of the circuit.

In various embodiments, every PROM cell is configured to be programmed to perform any function in the set of basic functions. In various embodiments, each PROM cell is configured to receive M inputs and S configuration bits, and generate an output, wherein M and S are integer numbers and the corresponding PROM cell is configured to perform 2^{S} unique functions using the S configuration bits. In various embodiments, the corresponding PROM cell comprises a function module and the function module comprises 2^{S} sub-function modules, wherein each sub-function module is provided with the M inputs and generates a corresponding sub-function output.

In various embodiments, the corresponding PROM cell further comprises a 2^{S}:1 multiplexer, configured to receive sub-function outputs of each of the 2^{S} sub-function modules and generate the output of the corresponding PROM cell using the S configuration bits.

In various embodiments, the corresponding PROM cell further comprises an S-bit register configured to store the S configuration bits, wherein the S-bit shift register is electronically coupled to a selection input of the 2^{S}:1 multiplexer. In various embodiments, the method includes incorporating each PROM cell in a netlist design of the circuit. In various embodiments, a subset of the M inputs are dummy inputs.

In various embodiments, the method comprises obfuscating the circuit design, wherein the obfuscation comprises. The obfuscation may include providing a fabrication specification for fabricating the set of PROM cells of the circuit design and fabrication or architectural requirements for each PROM cell, and hiding the dummy inputs in the fabrication specification.

In various embodiments, the PROM cell comprises a function module and the function module comprises 2S sub-function modules, wherein each sub-function module is provided with the M inputs and generates a corresponding sub-function output. In various embodiments, the PROM cell further comprises a 2S:1 multiplexer, configured to receive sub-function outputs of each of the 2S sub-function modules and generate the output of the PROM cell using the S configuration bits.

In various embodiments, the PROM cell further comprises an S-bit register configured to store the S configuration bits, wherein the S-bit shift register is electronically coupled to a selection input of the 2S:1 multiplexer. In various embodiments, the method includes incorporating each PROM cell in a netlist design of the circuit. In various embodiments, a subset of the M inputs are dummy inputs.

In various embodiments, the method includes obfuscating the circuit design. The obfuscation may include providing a fabrication specification for fabricating the PROM cells of the circuit design and fabrication or architectural requirements for each PROM cell; and hiding the dummy inputs in the fabrication specification.

A PRogrammable lOgic Macro (PROM) cell is provided in accordance with various embodiments of the present disclosure. The PROM cell may include a function module including M inputs, where M is an integer; 2^{S} operation circuitry, wherein S is an integer number and each operation circuitry comprises electronic components configured to perform a function on an input of the operation circuitry and generate an output of the operation circuitry; and a 2^{S}:1 multiplexer, configured to receive sub-function outputs of each of the 2^{S} sub-function modules and generate the output of the corresponding PROM cell.

In various embodiments, the PROM cell includes an S-bit register configured to store the S configuration bits, wherein the S-bit shift register is electronically coupled to a selection input of the 2^{S}:1 multiplexer.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

Having thus described certain example embodiments of the present disclosure in general terms, reference will now be made to the accompanying drawings, which are not necessarily drawn to scale, and wherein:

FIG. 1(a) and FIG. 1(b) are schematic diagrams illustrating cell structures, according to one or more embodiments herein;

FIG. 2(a), FIG. 2(b) and FIG. 2(c) are schematic diagrams illustrating various cell functions and architecture, according to one or more embodiments herein;

FIG. 3(a), FIG. 3(b) and FIG. 3(c) are schematic diagrams illustrating cell mappings, according to one or more embodiments herein;

FIG. 4 is a schematic diagram illustrating hierarchical cell structure, according to one or more embodiments herein;

FIG. 5(a) and FIG. 5(b) are schematic diagrams illustrating cell map design, according to one or more embodiments herein;

FIG. 6 is a schematic diagram illustrating configurable cell with AES, SHA-256 and Hash modules, according to one or more embodiments herein;

FIG. 7 is a schematic diagram illustrating a mapped cell, according to one or more embodiments herein;

FIG. 8(a), FIG. 8(b), and FIG. 8(c) are schematic diagram illustrating transistor level design, according to one or more embodiments herein;

FIG. 9 is a diagram illustrating a comparison, according to one or more example embodiments herein;

FIG. 10(a), FIG. 10(b), FIG. 10(c), FIG. 10(d), FIG. 10(e), FIG. 10 (f) are schematics illustrating transistor level design, according to one or more embodiments herein;

FIG. 11 is a graph illustrating a comparison, according to one or more example embodiments herein;

FIG. 12(a) is a schematic diagram illustrating a PROM, according to one or more embodiments herein;

FIG. 12(b) is a schematic diagram illustrating a PROM, according to one or more embodiments herein;

FIG. 12(c) is a flowchart illustrating a method, according to one or more embodiments herein;

FIG. 12(d) is a flowchart illustrating a method, according to one or more embodiments herein;

FIG. 13(A) is a flowchart illustrating a method, according to one or more embodiments herein;

FIG. 13(B) is a flowchart illustrating a method, according to one or more embodiments herein;

FIG. 13(C) is a flowchart illustrating a method, according to one or more embodiments herein;

FIG. 13(D) is a flowchart illustrating a method, according to one or more embodiments herein

FIG. 14 is an example apparatus, according to one or more embodiments herein.

### DETAILED DESCRIPTION

Embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

The phrases “in one embodiment,” “according to one embodiment,” “in some embodiments,” “In various embodiments” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

The term “electronically coupled,” “electronically coupling,” “electronically couple,” “in communication with,” “in electronic communication with,” or “connected” in the present disclosure refers to two or more elements or components being connected through wired means and/or wireless means, such that signals, voltage/current, data and/or information may be transmitted to and/or received from these elements or components.

Logic locking and obfuscation are some of the solutions used for protecting confidentiality of the IP in logic design. The logic locking enables a designer to introduce locking gates which help prevent unauthorized usage without knowledge of an unlocking key. Some solutions may include logic redaction, which replace certain logic in a design with programmable fabrics such as Look-Up-Tables (LUTs) and/or structured ASICs. However, these solutions may result in prohibitive area overheads and/or potential vulnerability to newer structural attacks, such as Structural Analysis using machine Learning (SAIL).

Various embodiments of the present disclosure provide PRogrammable lOgic Macro (PROM) cell architecture. The proposed methods and techniques may be used to design a configurable and diverse cell library which may incur considerably less area overhead compared to existing logic redaction-based obfuscation techniques, while maintaining security against state-of-the-art attacks on confidentiality.

Various approaches to hardware assurance may involve using logic redaction to protect hardware intellectual property (IP) confidentiality. Logic redaction approaches may replace underlying Boolean functions with highly configurable and programmable Look-Up-Table (LUT)-based obfuscation techniques or Structured ASIC cells with large number of functions. The redacted functions are unknown unless correctly programmed. While these techniques may protect IP confidentiality, they may come at the cost of large area overhead due to the high configurability. To overcome these issues, various embodiments herein provide methods and techniques to design and introduce a configurable standard cell library to enhance the security of a design with reduced area overhead and improved security compared to LUT-based or structured ASIC logic redaction approaches.

Various embodiments herein provide:
Methods and techniques to generate a standard cell library with custom multi-input and multi-output configurable logic cells, which also may be referred to as PROM cells herein.
Methods and techniques for introducing PROM cells in a netlist design.
Methods and techniques to introduce a diverse set of PROM cells by varying the underlying functions, number of inputs to respective functions, dummy inputs to functions, and number of outputs of PROM cells.
Methods and techniques to increase the configuration and diversity of PROM cells to increase the security of the underlying design.
Methods and techniques to randomize the interconnect by changing a set of PROM cells used.
Methods and techniques to reduce the area overhead by sharing configuration bits.
A PROM cell library design with multiple overlapping functions across different set of PROM cells.
A hybrid PROM cell architecture which utilizes already present PROM cells in custom cell library and dynamically generated PROM cells while remapping a design to only PROM cell library. The hybrid cell approach can be directly applied to design or by partitioning the design.
A hierarchical PROM cell architecture in which functions in PROM cells are subset of already present function in the respective PROM cell.
Methods and techniques to optimize the PROM cell area at the Transistor level for reduced overheads. The customized transistor level PROM cells are designed to have less transistor count compared to when the PROM cells are design with standard library cells.
Integration of various method and techniques of the present disclosure with electronic design automation (EDA) synthesis tools by for example updating the library files needed to synthesize a design.

The following terminology may be used in various sections of the present disclosure.

Functions: Gate level representation of a Boolean expression.
Cell: A system block with multiple functions.
Cell Inputs number (M): Number of inputs of a cell.
Cell Output number (N)—Number of outputs of a cell.
Configuration bits number (S)—Number of bits to configure a cell.

In various embodiments, configurable standard cells can be seamlessly integrated with existing commercial EDA tools such as Synopsys® design compiler. In various embodiments, to introduce the PROM cells into the design, an EDA tool can be used to re-synthesize a design to basic set of functions which are used in all the PROM cells. Once a design is mapped to PROM functions, a wrapper is placed around the functions to create PROM cell which contains and/or implements the current function in consideration along with set of configuration bits. In example embodiments, a wrapper is a system of different functional units that are integrated together such as in System on Chips (SoCs). The value of configuration bits may determine the correct function to be used for respective PROM cell. The current function can be present in multiple PROM cells which helps in increasing the diversity of PROM cells in the re-synthesized design. Various embodiments of the present disclosure provide details on how the PROM cells can be constructed, how a design gets mapped to PROM cells and/or described using PROM cells and different ways to introduce PROM cells in design.

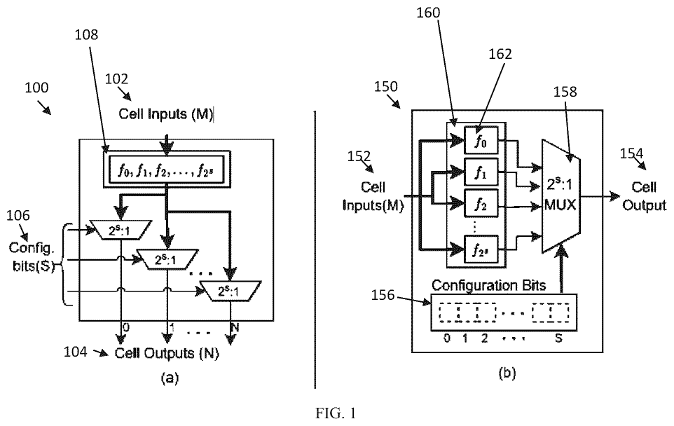

Referring now to FIG. 1, generalized PROM cell structures with M inputs, N outputs and S configuration bits in FIG. 1(a), and M inputs, 1 output and S configuration bits in FIG. 1(b) are presented in accordance with various embodiments of the present disclosure.

FIG. 1(a) illustrates proposed generalized MxNxS PROM structure 100 with M number of cell inputs 102, N number of cell outputs 104, and S cell configuration bits 106. The arrows from the input to the function module 108 and from the function module 108 to the multiplexers are used to show multiple input/output connections. For example, a cell can have multiple inputs(M) which can be partially or fully connected to all the possible functions used in the cell. In various embodiments, the function module 108 provides a function module output that is the transformed cell input based on any of the 2^{S} possible functions of the PROM cell. The PROM cell then uses the configuration bits and an array of multiplexer to select the output corresponding to a specific combination of configuration bits.

In various embodiments, for multi-output cells the outputs of these functions will be connected to respective multiplexed cells. Here, configuration bits control the size of the multiplexed logic to be used and also decides which one of the functions will be used based on the configuration bit value. The values of configuration bits used within the cell for N different outputs can be either same or different.

FIG. 1(b) illustrates Mx1xS PROM structure 150 with single output 154, S number of configuration bits 156 to control the driving functions of the cell output and M number of cell inputs 152. For S configurable bits, the cell can be designed to have maximum 2^{S} possible unique functions as shown by each operation circuitry 162 of the function module 160. In various embodiments, each operation circuitry 162 performs a unique function on the input 152. The multiplexed logic block 158 may then select the appropriate output of the function module based on the combination of the configuration bits, as the cell output 154.

For example, when the function ƒ₀ is connected to the first port of the multiplexed logic block 158, then all the configuration bits should be set to 0 in order to choose the function ƒ₀ as the function the PROM cell 150 performs. Similarly, if the function ƒ₂^{s} is connected to the last input port of the multiplexed logic block the configuration bits should be set to 1 to select function ƒ₂^{s} as the function the PROM cell 150 performs.

### Diversity in PROM Cells

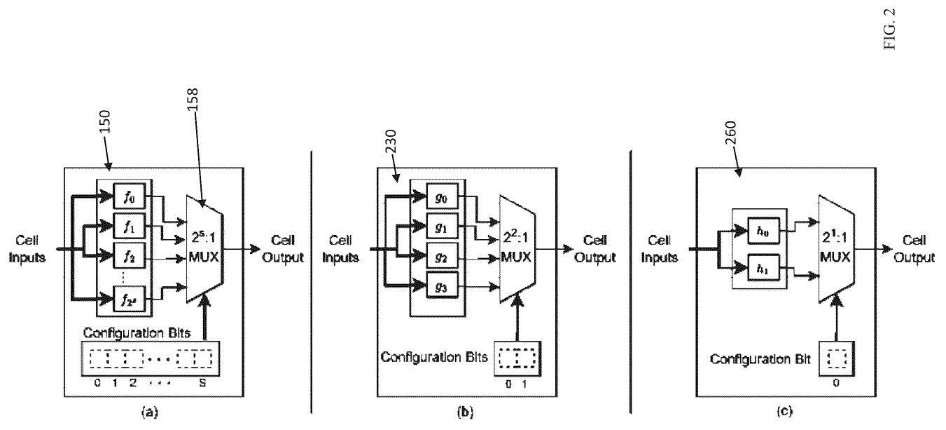

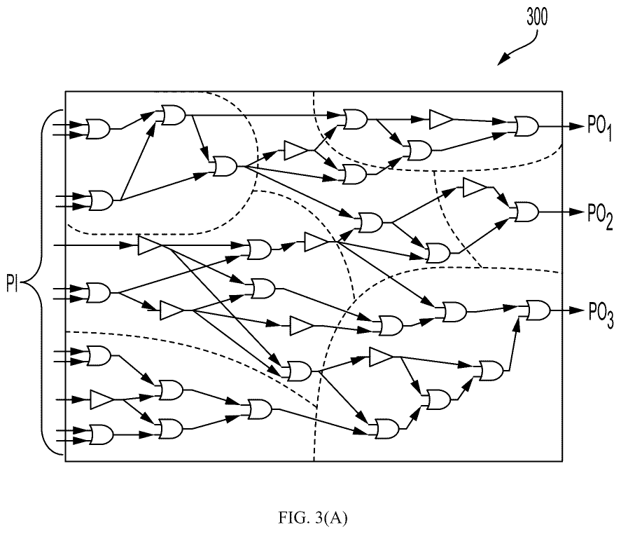

Referring now to FIG. 2, PROM cells with diverse functions and diverse configurability are presented in accordance with various embodiments of the present disclosure.

In various embodiments, as shown in FIG. 2, for a PROM cell 150 the number of inputs driving a multiplexed logic 158 can be changed by varying the S parameter. For example, for a PROM cell 230 with 2 configuration bits, there can be maximum of 4 different functions used as shown in FIG. 2(b). For a PROM cell with 1 configuration bits, a maximum of 2 different functions can be used within the PROM cell 260 as shown in FIG. 2(c). The number of maximum possible functions are directly related to number of configuration bit as described by 2^{S}. In various embodiments, the configurability parameter comes at cost. It will enhance the security but at the same time it may increase the area overhead. Having a single PROM cell in custom library with all possible function will increase the security but it may also increase area overhead by a significant amount, which is the case with structured ASIC.

FIG. 2 illustrates how the proposed PROM architecture can be used to create diversity in the PROM cells in order to create a library of custom cells, in accordance with various embodiments of the present disclosure. FIG. 2(a) illustrates generalized PROM cells with different set of functions ƒ₀, ƒ₁, . . . , ƒ₂^{s}. In various embodiments, based on the number of cell inputs and number of configuration bits used, the diversity of PROM cells can be increased. FIG. 2(b) illustrates a variation in PROM cells with 2 or more inputs to 4 set of functions g₀, g₁, g₂, g₃. FIG. 2(c) is Mx1x1 PROM cells with just one configuration bits hence allowing only two possible functions h₀, h₁. In various embodiments, to increase the diversity in the PROM cells, individual functions within PROM cell can be overlapped with other PROM cells. This enables the selection of different variations of PROM cell with the required function. If the primitive functions within PROM cells are not overlapping other PROM cells, the user becomes restricted to a limited set of PROM cells. This restriction may reduce the overall security as the presence of this PROM cell can form a relationship with the singular function (i.e., this PROM cell means this function is used). In various embodiments, the number of inputs M can also be varied to further increase the diversity of PROM cells. In various embodiments, any of the following components in PROM cells can be varied to create diverse set of custom PROM cells:
The number of functions to be used within the PROM. Also referred to as configurability of the cell.
The overlap of functions across PROM cells.
The number of inputs to functions in PROM cells.
The way inputs of a cell are connected (partial/full connection).
The number outputs of a PROM cell.
The type of functions in a PROM cell.

### Hybrid PROM Cell Library

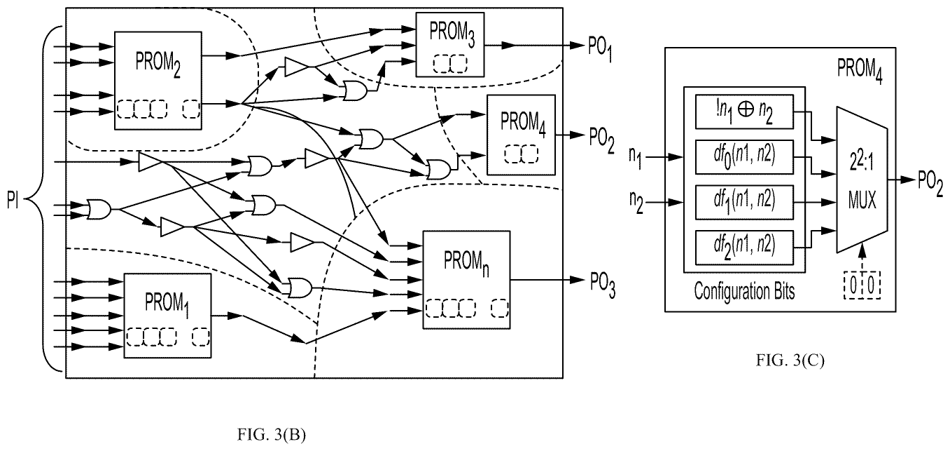

Referring now to FIG. 3, a partitioned based PROM cell mapping with hybrid or custom PROM cell library is provided in accordance with various embodiments of the present disclosure.

In various embodiments, while synthesizing the design to proposed PROM cells, hybrid PROM cells can also be introduced as shown in FIG. 3. The hybrid PROMs can be designed while mapping a design to PROM cells by either using already present custom cells in the library or by introducing a new set of PROM cells on-the-go. In various embodiments, custom PROM cells are designed at the transistor level, whereas on-the-go cells are constructed from standard library cells. FIG. 3(a) shows a gate level design 300 with its IOs (primary inputs/primary outputs) and internal structure, in accordance with various embodiments. FIG. 3(b) illustrates hybrid PROM that may be used to increase the security of the design in accordance with various embodiments. The design may be partitioned into smaller segments. For each partition, a custom PROM cell from the custom PROM cell library may be used if the function of the partition is already present otherwise a new PROM cell with the partition logic is designed from existing standard cells. In the generated PROM cells, one of the functions may be the original function in the partition and the remaining functions may be introduced based on the number of configurable bits used for the respective PROM cells. In this way, the original functionality may get hidden among incorrect functions of the PROM cell. For example, a correct configuration selects a correct functionality, and the incorrect functions will be overhead. Only the designer knows the correct set of configuration bits to restore the function of the design. As shown in FIG. 3(b), the n number of PROM cells may be constructed from either custom PROM cells or on-the-go PROM cells, all with different cell input size, in accordance with various embodiments of the present disclosure. In various embodiments, the number of configuration bits determines the difficulty of guessing the correct function. FIG. 3(c) shows zoomed-in version for PROM₄. Here, if the original function (!IN₁ ⊕IN₂), where ! denotes negation and @ denotes exclusive OR, is already present in one of the custom PROM cells, then the respective PROM cell can be used to map (♭n1⊕n2) otherwise the original function in the design (!n1⊕n2) gets mapped to 0^{th} function in PROM₄. Because there are 2-bits of configuration, an additional 3 functions are introduced. In various embodiments, the type of the functions introduced may provide increase in the diversity and thus increasing the security of the system.

### Hierarchical PROM Cells

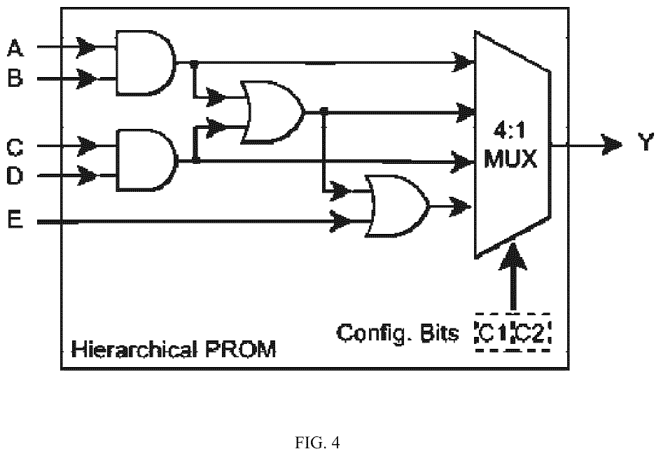

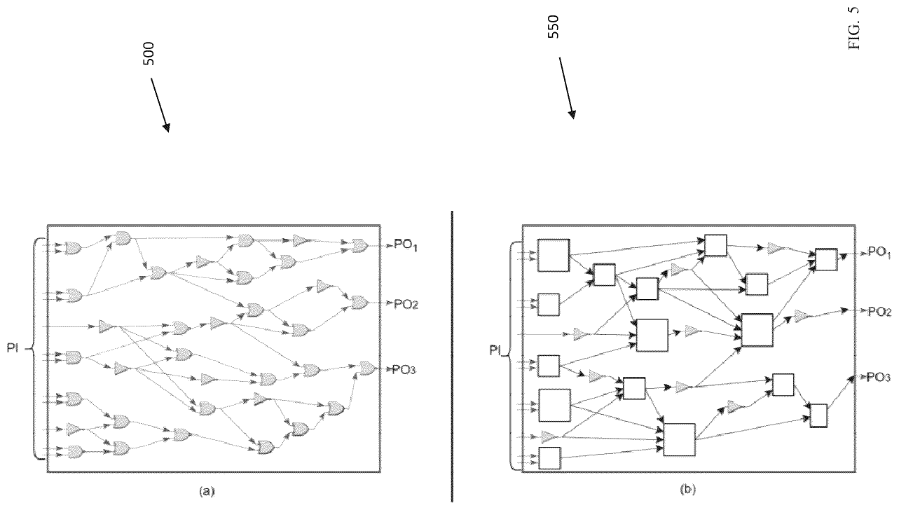

Referring now to FIG. 4, a hierarchical PROM cells is illustrated in accordance with various embodiments of the present disclosure. In various embodiments, for designs with area constraints which require additional security, a set of hierarchical PROM cells can be used. FIG. 4 shows one instance of such a hierarchical PROM cell. Here, additional functions of PROM cells may be derived from already present function(s) in the current PROM cell. In various embodiments, the configuration bits (multiplexer's input/output map) hide the design and/or determine the correct functionality of the design. The logic is shared in a hierarchical embodiment and only the additional area of the multiplexer gets added to the overall area. Hence, this architecture helps in reducing the area overhead. As shown in FIG. 4, for 5 input PROM cell with 2 configuration bits, additional 3 functions are introduced in order to choose either of the possible 4 inputs of multiplexed logic, in accordance with various embodiments. Here, additional functions are derived from the logic cone of the first function itself. This will help in reducing the area overhead introduced by PROM cells and it will increase the security as the attacker has to choose one of the four possible functions from the PROM cell. For example, the re-use of the functions and/or not adding the overhead of providing false functions may cause reducing the area overhead. The hierarchical PROM cells can be pre-defined in the PROM cell library, or these types of cells can be designed dynamically as previously described.

### Custom PROM Cell Library

Referring now to FIG. 5, a PROM mapped design with custom cells is provided in accordance with various embodiments of the present disclosure.

In various embodiments, FIG. 5 shows how a design 500 as illustrated by FIG. 5(a) gets transformed after introducing proposed custom PROM cells 550 as illustrated by FIG. 5(b). Here, a pre-built custom cell library functions are provided to a synthesis tool. The tool maps the design to the functions that are present in the library. Then all the function mapped in the designs are replace with respective PROM cells which contains the desired function and other security and area constraints. For example, a single function can be present in multiple PROM cells to increase the diversity of PROM cells in the design.

### PROM Cells for Multi-Mode Systems

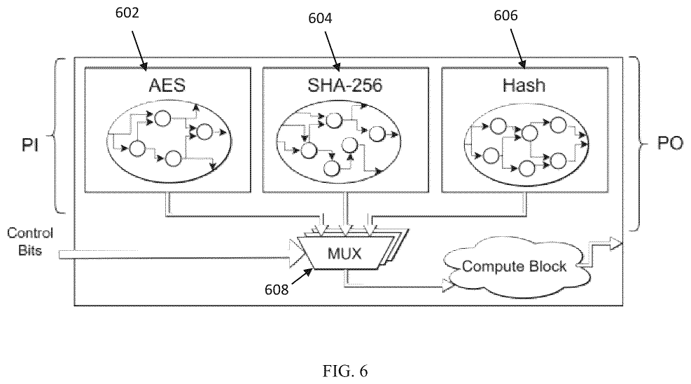

Referring now to FIG. 6 a system with configurable AES, SHA-256 and Hash modules is provided in accordance with various embodiments of the present disclosure.

In various embodiments, the PROM custom cells and methodology may have an inherent advantage to be used for multi-mode systems. In various embodiments, to design a multi-mode core, three functional units including AES 602, SHA-256 604 and Hash modules 606 may be implemented in parallel with a control logic, for example the multiplexer 608, to select the desired function as for example shown in FIG. 6. However, this may come at the cost of area. Alternatively, to achieve similar objective, one can use PROM mapping with multiple valid configurations to select among several alternate functionalities. The alternate functionalities need to be selected during PROM mapping to ensure availability of the correct hardware. The compute bock in FIG. 6 illustrates a remainder of the design that makes use any of the encryptions to secure the system.

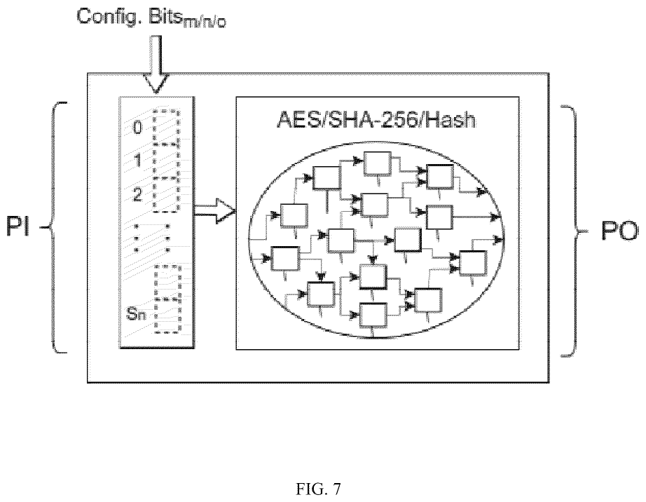

Referring now to FIG. 7, a multi-mode PROM mapped design with custom cells to achieve different functionality is provided in accordance with various embodiments herein.

As shown in FIG. 7, the functions of individual PROM cells may be selected such that the design uses AES, SHA-256 or Hash functionality based on Configuration Bits m, n or o. n various embodiments, PROM cells used as such achieve area savings by resource sharing as opposed to implementing three separate functions. Though the security of the system reduces as the number of valid configurations increases by the number of additional functionalities introduced, the overall security is still very high as there are (2^{config._bits}—No. of valid configurations) invalid configurations and/or combinations. This can be mitigated by time-multiplexing or scheduling the configuration bits such that at a particular time instance only one set of configuration bits will be valid. In this way, PROM can achieve more complex functions without additional hardware.

### PROM Cell Optimization at Transistor Level

In accordance with various embodiments of the present disclosure, transistor-level optimization is provided to reduce area overhead and enhance overall performance in integrated circuits. An example advantage of transistor-level optimization is due to resource sharing. In various embodiments, by strategically allocating and sharing resources among multiple circuit elements, area overhead may be reduced, while maintaining or even improving the overall performance of integrated circuits. This approach may not only streamline the layout design but may also enable the integration of multiple functionalities within a compact space, resulting in highly efficient and cost-effective semiconductor solutions in various examples. In example embodiments, by integrating multiple functionalities within a single PROM block, performance and efficiency is enhanced. This compact and versatile design may effectively reduce and/or minimize the area overhead, enabling the implementation of diverse set of functions. Therefore, in example embodiments, implementing optimization techniques on PROM cells enhances performance and resource utilization, resulting in higher computational power while preserving an economical footprint.

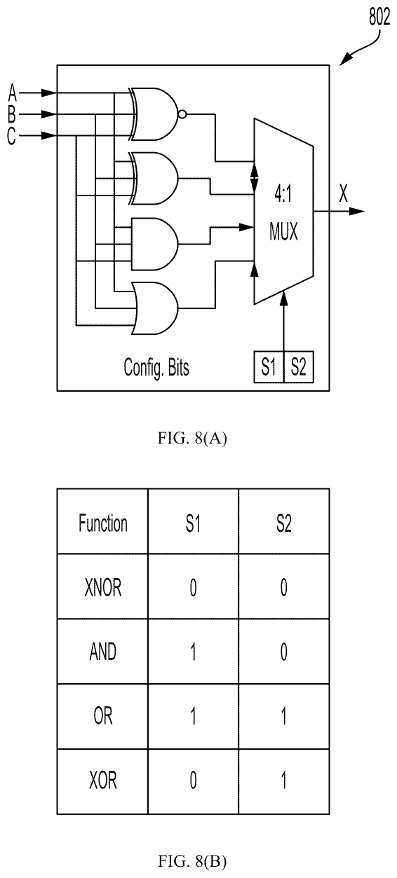

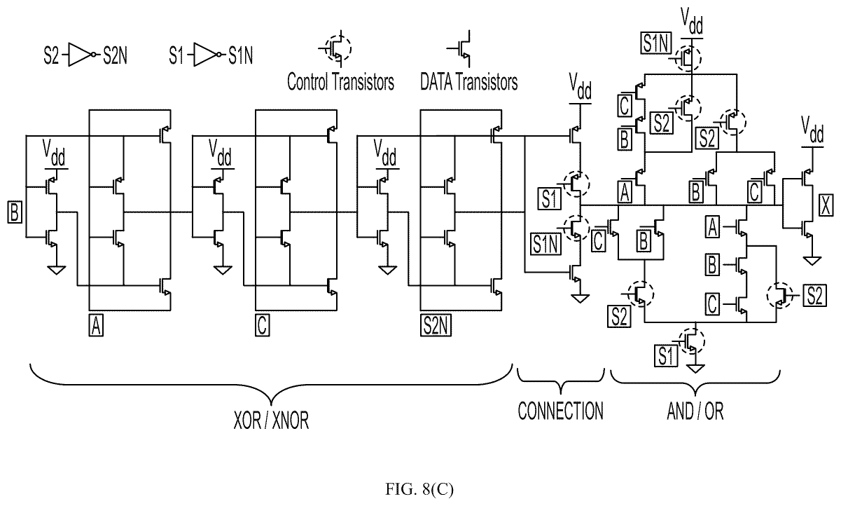

1) PROM-C Optimization: FIG. 8(a) illustrates a 2-bit configurable PROM-C block 802 having four distinct functions of XNOR, XOR, AND, and OR and is presented as an example to illustrate improved performance and reduction of area overhead provided by various embodiment of the present disclosure. The PROM-C cell 802 is designed to take three inputs, A, B, and C. Depending on the configuration of S1 and S2, the output will be one of the four functions: XNOR, XOR, AND, or OR. FIG. 8(b) illustrates configuration bit values and their corresponding function in accordance with an example provided by FIG. 8(a).

When considering the implementation of the PROM-C cell using standard cells from the Process Design Kit (PDK) of an IC manufacturers, it is important to note that the number of transistors required for this cell may be relatively high. Consequently, such implementation could consume a significant amount of space on the die. Therefore, there is a trade-offs between using standard cells and exploring alternative approaches, such as custom circuitry. As provided by various embodiments of the present disclosure, striking the right balance between area efficiency, delay, power consumption, and performance is important in ensuring optimal integration of PROM cells into the final design.

FIG. 8(c) illustrates one of several possible optimized versions of PROM-C block 802 using resource sharing in accordance with various embodiments of the present disclosure. As shown by FIG. 8(c), Depending on the configuration bits provided, the output of one of the four functions, namely XNOR, XOR, AND, or OR, will be directed to the output. In this optimized design, the transistors marked with a dashed circle serve as a mux and perform a similar task to the 4:1 mux found in a PROM cell designed with standard cells. These mux transistors play an important role in routing and selecting the appropriate signals to achieve the desired functionality efficiently and effectively. This design in accordance with various embodiments comprises primarily two sections: the AND/OR section and the XOR/XNOR section. Depending on the value of S1, one of these two sections becomes activated, while the other is disconnected from the output. For example, when S1 is 0, the output is determined by the XOR/XNOR section, and when S1 is 1, the AND/OR section is used to determine the output. Furthermore, the configuration bit S2 is utilized to select specific functions within each section. For example, when S1 is equal to 1, setting S2 to 1 results in the selection of the OR function for the activated AND/OR section, while setting S2 to 0 selects the AND function. Similarly, when S1 is equal to 0, the same rule applies for the XOR and XNOR functions within the activated XOR/XNOR section. In various embodiments, the dynamic interplay between S1 and S2 allows for versatile and precise customization of the PROM cell's behavior, ensuring adaptability to various operational requirements.

Various performance comparisons between the implementation of the PROM-C cell 802 and the resource sharing optimization at the transistor level are provided herein. To ensure a fair and equitable comparison, the PROM-C block was implemented using a same technology (TSMCR 65 nm) for both the design with standard cells and the design with the optimized version. Notably, all PMOS and NMOS transistors used in the optimized PROM cells were set to have the same (W/L) as the transistors utilized in the design with standard cells. Additionally, the sizes of the transistors are matched in order to precisely assess the effect of the optimization, while keeping the comparison fair. Table I shows the transistors needed for the implementation of both designs. Utilizing the optimized design allows us to achieve significant savings, surpassing 54% compared to implementing the PROM-C block with standard cells. This substantial reduction in transistor count demonstrates the effectiveness and efficiency of the optimized version, making it a highly favorable choice for implementation needs.

TABLE I
Transistor Count Comparison

| Function | AND | OR | XOR | XNOR | MUX | Total |
|---|---|---|---|---|---|---|
| Standard | 8 | 8 | 22 | 22 | 26 | 86 |

| | | | | |
|---|---|---|---|---|
| Optimized | 12 | 20 | 8 | 40 |

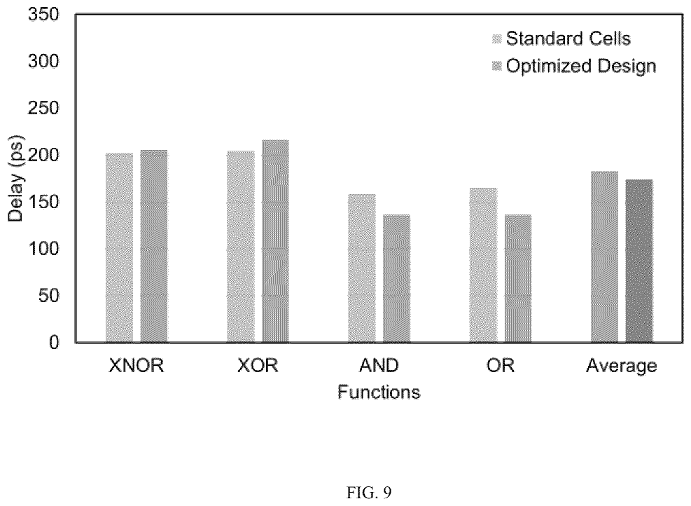

In addition to the transistor count analysis, both designs are evaluated in terms of delay as provided in the present disclosure. Evaluating the delay performance is important to understanding how each design functions under different operating conditions and helps to gauge their overall efficiency and speed. FIG. 9 illustrates a delay comparison between standard cell (e.g. 802) vs. the optimized design at the transistor level. The graph in FIG. 9 illustrates the delay calculation, considering changes on inputs A, B, and C and observing the corresponding response at the output of the PROM-C block. These measurements are conducted using the TSMCR 65 nm technology node and at a simulation temperature of 27 degrees Celsius. As shown in FIG. 9, in example embodiments, the optimization of the PROM-C block not only reduces the amount of die area used but also does not have a negative impact on the total delay in the PROM-C block. This favorable outcome can be attributed to the design's efficient structure. In the case of the standard cell design, the signals had to pass through two stages, one for the logic gates and another for the 4:1 mux. However, the optimized design integrates the 4:1 mux inside the logic gates, resulting in a single-stage path. This integration effectively mitigates the increased delay that could have occurred as a result of the added parasitic capacitance on the main path of the optimized design. As a result, the optimized version of the PROM-C block delivers improved performance without compromising on delay characteristics.

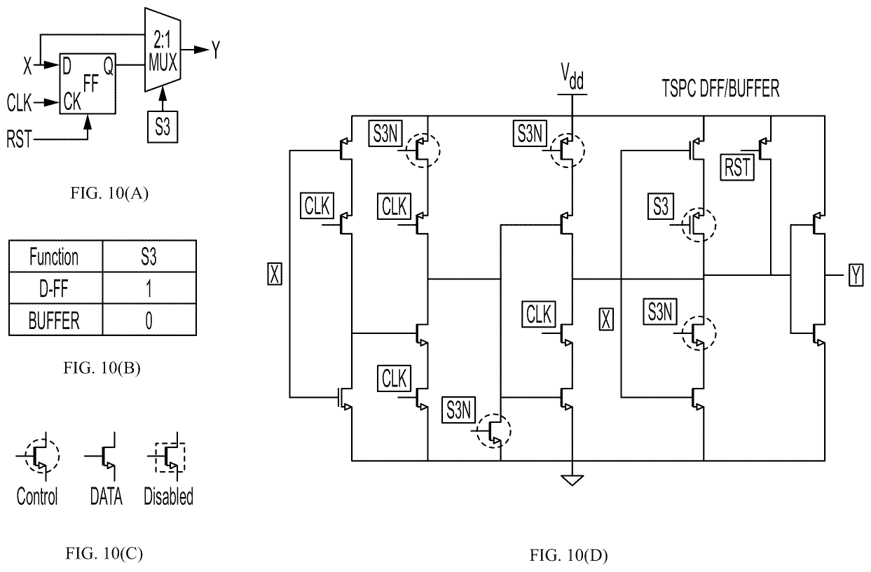

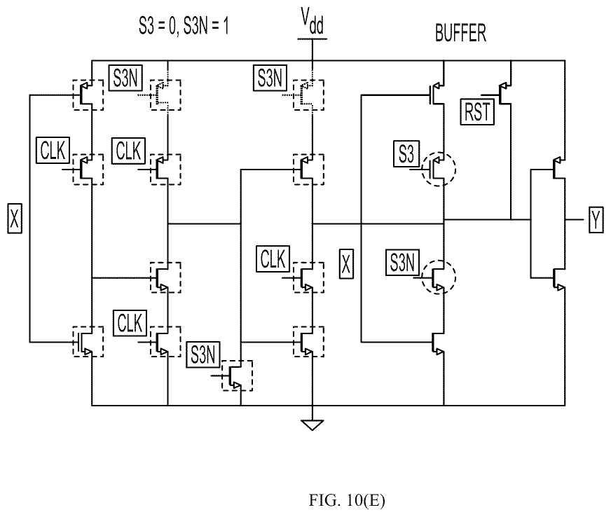

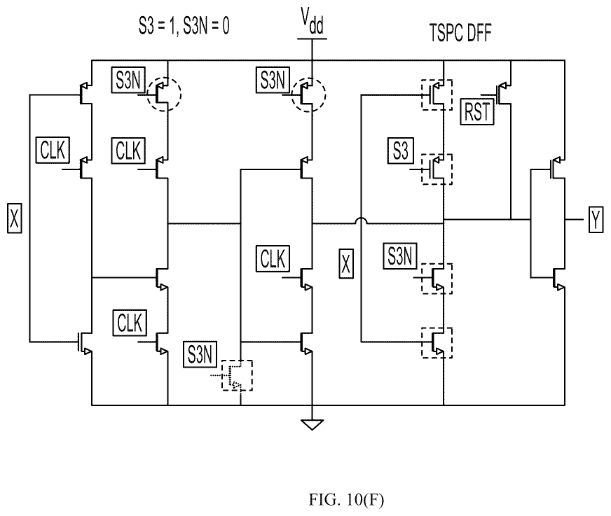

2) PROM-S Optimization: By analyzing the circuit and employing design strategies, in accordance with example embodiments of the present disclosure, improvements in both die area consumption and delay characteristics for the PROM-S implementation are achieved. FIG. 10(a) illustrates a D flip-flop (DFF) and a 2:1 Mux as part of a PROM-S. For example, based on the configuration bit S3, the data X is routed to the output Y, either through a DFF or directly transmitted. In various embodiments, the PROM-S cell in FIG. 10(a) has its input driven by the PROM-C cell discussed earlier. The PROM-C signal can be routed in two ways depending on the setting of the configuration bit S3. If it is set to “1”, the signal will go through a D Flip-Flop (DFF) and a 2:1 multiplexer before reaching the output of PROM-S. On the other hand, if S3 is set to “0”, the signal will bypass the DFF and directly enter the multiplexer, then to the output of PROM-S. FIG. 10(b) illustrates corresponding functions to configuration bits. As illustrated by FIG. 10(c) a control transistor is shown using a dashed circle, and a disabled transistor is shown using a dashed square. Other transistors are DATA transistors. FIG. 10(d) illustrates optimized transistor-level design for integration of the resource sharing technique in accordance with various embodiments. FIG. 10(e) illustrates a transistor-level design for when S3=0, in which the design functions as a buffer, transmitting data X directly to the output. FIG. 10(f) illustrates a transistor-level design for when S3=1, and the entire design functions as a TSPC DFF.

In accordance with various embodiments of the present disclosure, a similar optimization approach employed in PROM-C can be utilized for the 2:1 multiplexer, which can be included in the DFF. To achieve this, a True Single-Phase Clock (TSPC) flip-flop has been used in an example herein. TSPC DFFs generally have high operational speed and low power consumption, making them advantageous to static flip-flops in these aspects. In example embodiments, by integrating the 2:1 mux inside the TSPC DFF, the efficiency and performance of the circuit may further enhance, resulting in a more compact and power efficient design. FIG. 10 shows a potential way to enhance the DFF and mux section of PROM-S. This design includs multiple control transistors, allowing it to be used either as a typical TSPC DFF or as a buffer (two inverters in a row) depending on the settings of the configuration bit. By cascading the previously optimized PROM-C and the design incorporating the TSPC DFF and mux section, we can achieve the final optimized PROM-S cell.

To establish a fair comparison, both the standard cell design and the optimized version of the PROM-S cell were implemented using TSMC 65-nm technology. Table II presents the transistor count for both designs. In particular, the optimized PROM-S design utilizes 69 less transistors than the standard cell design, showcasing a remarkable 53 percent improvement in area consumption.

TABLE II
transistor count comparison for two prom-s structures

| | PROM-C | 2:1 Mux | DFF | Total |
|---|---|---|---|---|
| Standard | 86 | 12 | 30 | 128 |

| | | | |
|---|---|---|---|
| Optimized | 40 | 19 | 59 |

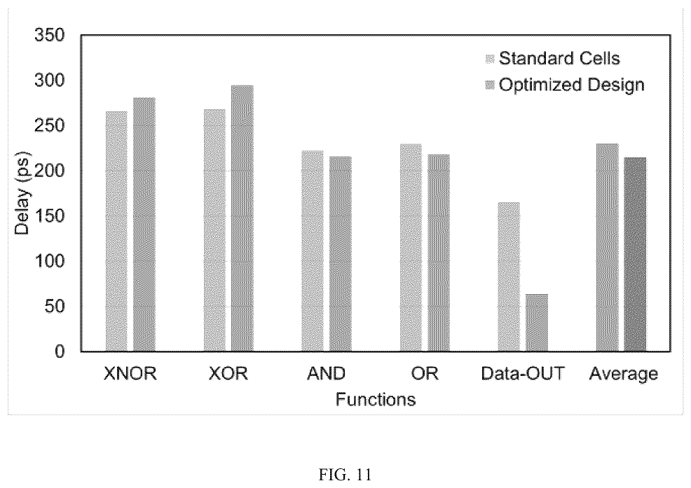

Standard cell and optimized implementations of PROM-S cells are also characterized in terms of delay in accordance with various examples herein. PROM-S has two distinct pathways that influence the total delay. The first route involves inputs A, B, and C going through PROM-C, then going through the 2:1 mux before arriving at the output of PROM-S. The second path is from the input of the DFF, through the 2:1 mux, and eventually reaching the output of PROM-S. For the second path, the clock was considered as the reference for delay measurement in both designs. This delay is denoted as Data-OUT in our measurements. FIG. 11 illustrates the measured delay for these two distinct paths. When considering FIG. 11 and Table II, it is evident that the optimized designs in example embodiments, not only have a negligible impact on delay, but also result in considerable reductions in area usage.

The above PROM-S optimized design is provided as a non-limiting example and the optimized design in accordance with various embodiments of the present disclosure is not limited to this example with its defined four functions. In accordance with various embodiments, the optimization process can be extended to any arbitrary PROM-S, with any distinct built-in functions. The optimized design in accordance with various example embodiments herein provide improvements in area consumption and delay.

### Security Analysis

In various embodiments, to assess the security of the custom PROM cells in accordance with various embodiments, the following types of functional and structural attacks may be performed:
Brute force attack.
Functional attacks for example satisfiability (SAT) attack.
Structural attacks for example Structural Analysis using Machine Learning (SAIL) attack.

In various embodiments, for brute force and other functional attacks like SAT, the attacker is assumed to have access to the original design (called oracle), PROM remapped design, access to primary inputs(I) of the original design, structure/functions inside the PROM cell and additional key inputs(K) introduced by the PROM cells (for example the configuration bits in accordance with various embodiments of the present disclosure). For the brute force attack, key inputs are iteratively varied to check if the outputs of the locked design matches against output of the oracle with same primary input test vector. Hence, the attacker needs to perform an exhaustive search of 2^{K+1} test patterns in order to find the correct key input bits. In an example embodiment, K is the number of configuration bits. In accordance with various embodiments, the input space will become exponentially large when the entire design is remapped with PROM cells making brute force attacks infeasible.

In various embodiments, for SAT attacks, PROM cells offer the following inherent benefits in example embodiments: (1) introduction of large key space, and (2) introduction of SAT-resistant dummy primitive functions inside PROM cells. In example embodiments, these two properties of the PROM cell methodology can reduce the success of SAT-based attacks as compared to traditional locking and other logic redaction techniques.

Structural attacks like SAIL are generally oracle-less. For this threat model, the attacker is assumed to have access to only the locked/PROM remapped design, knowledge of original primary inputs, knowledge of added key inputs and the functional contents of each of the PROM cells. In example embodiments, to reduce the success of SAIL-like attacks, PROM has the capability to include a large number of dummy functions across all PROM cells, which creates bad training data. Introducing the possibility of incorrect mappings as training data (bad training) may reduce the effectiveness of SAIL. Additionally, in various embodiments, while remapping the design with PROM cells, the interconnection and placement among PROM cells may be randomized in such a way that there will be no apparent structural signature left for SAIL to learn from.

### Example Methods

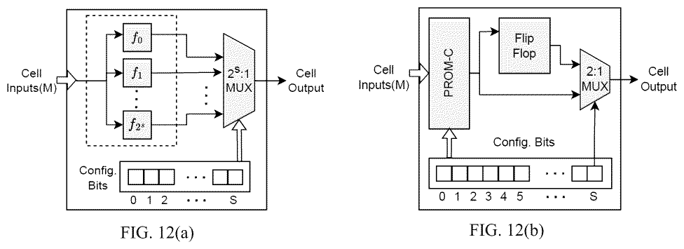

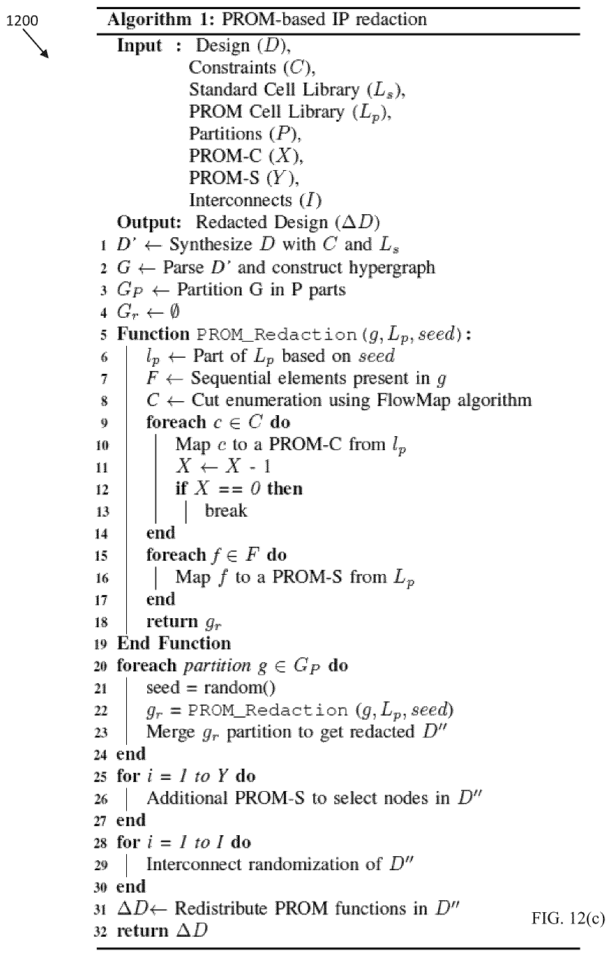

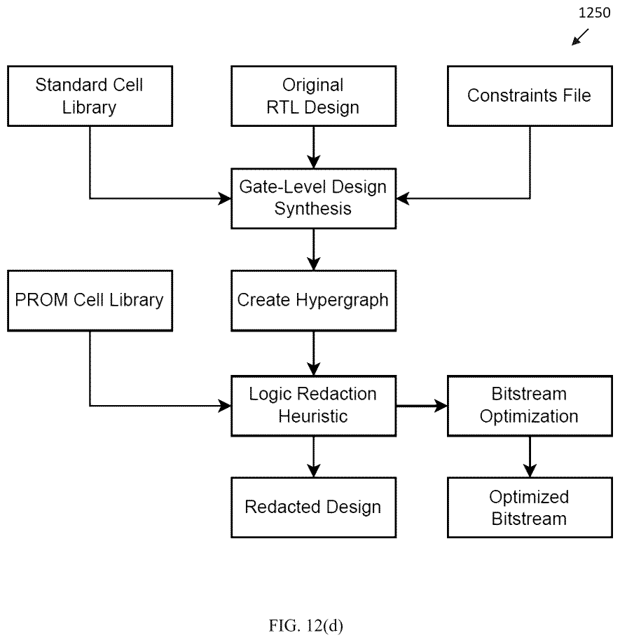

Referring now to FIGS. 12(a) and 12(b), generalized PROM-C and PROM-S structures are provided in accordance with various embodiments of the present disclosure. FIG. 12(c) illustrates method 1200 and FIG. 12(b) illustrates high level method 1250 for PROM based redaction.

As described by method 1250, in accordance with various embodiments, a gate-level design is synthesized for a given input register-transfer level (RTL) design with its constraint file and standard cell library. The gate-level netlist may be parsed to get the hypergraph of the design under consideration. Logic redaction heuristics may then be applied as described in method 1200 to generate the redacted design along with the bistream needed for its function.

In accordance with various embodiments, method 1200 provides steps that may be included in the redaction technique. The input to the method may be the design(D), PROM cell library(L), number of partitions(P) percentage of the design to be redacted with PROM-C cells(X), percentage of design to be integrated with additional PROM-S cells(Y), and the number of interconnects(I) to be introduced into the design. In various embodiments, the PROM cell library is a custom cell library that includes multiplexed complex gates as for example shown in FIGS. 12(a) and 12(b). FIG. 12(a) illustrates a generalized structure of the PROM-C cell including combinational functions f₀, f₁, . . . , f₂^{S} with M possible inputs, muxed with 2S:1 mux with selection bits S which also may be referred to as configuration bits. Thus, each PROM-C cell can be configured as an MxSx1 cell. FIG. 12(b) illustrates a generalized PROM-S cell including a PROM-C cell followed by a sequential element and a multiplexer (mux). Thus, in various embodiments, the combined configuration bits decide the driving function of the output of a PROM-S cell. In various embodiments, as for example shown in line 1 of the method 1200, the method 1200 generates gate-level netlist of the original design by synthesizing the design using given constraints and standard cell library. Then, the gate-level netlist is parsed to create a hypergraph of the design, as shown in line 2.

Next in line 3, the graph is partitioned into P parts using a partitioning tool like Hmetis®. Following lines 20 to 24, PROM-redactions are carried out simultaneously for each of the partitions, and the redacted partitions are combined to create a redacted design for the entire design. Details about PROM redaction, in accordance with various embodiments, are described in lines 5 to 19. For example, for each of the partitions, a portion of library cells (lp) is utilized to enhance the diversity of PROM cells in the design, as demonstrated in line 6. Subsequently, a FlowMap method may be employed to carry out the cut enumeration. The cuts with the respective inputs are assigned to the PROM cells in lp which contains the required function, and the total number of cells that need to be replaced is decreased, as demonstrated in lines 9 to 14. In various embodiments, in case of Look-Up Table (LUT)-based redaction these cuts are replaced by LUTs. The use of LUT-based redaction may increase security, but with a high area overhead. The proposed PROM-based redaction in accordance with example embodiments of the present disclosure, offers similar and/or better security benefits, but with a lower area overhead.

In various embodiments, once the given percentage of PROM-C cells are remapped, the sequential elements are redacted with PROM-S cells for the partition under consideration. Finally, additional PROM-S cells may be mapped to select nodes in the merged graph to further enhance resilience against reverse engineering attacks. In various embodiments, in the steps shown in line 28 to 30, interconnect randomization is performed to modify the data flow graph of the design. Connections between PROM cells from different partitions are established to PROM cells with dummy inputs, while making sure no combinational loops are formed.

In example embodiments, interconnects do not interfere with the functionality and help in decorrelating redacted design with the original design. The LUT-based redaction technique ensures uniformity in the design by default due to the similar LUT structures. As demonstrated in line 31, the approach in accordance with various embodiments of the present disclosure, achieves uniformity in terms of the number of functions used in all the PROM cells by redistributing them. To do this, the redacted PROM cells are replaced with different variations of PROM cells that contain the necessary function, or dummy inputs are added to the PROM cells to normalize the distribution of PROM functions. The redacted designs are provided as the output, along with the correct functional key to make the design operational. The bitstream, also known as the functional key, may be optimized to minimize the area overhead as described in the transistor level optimization section.

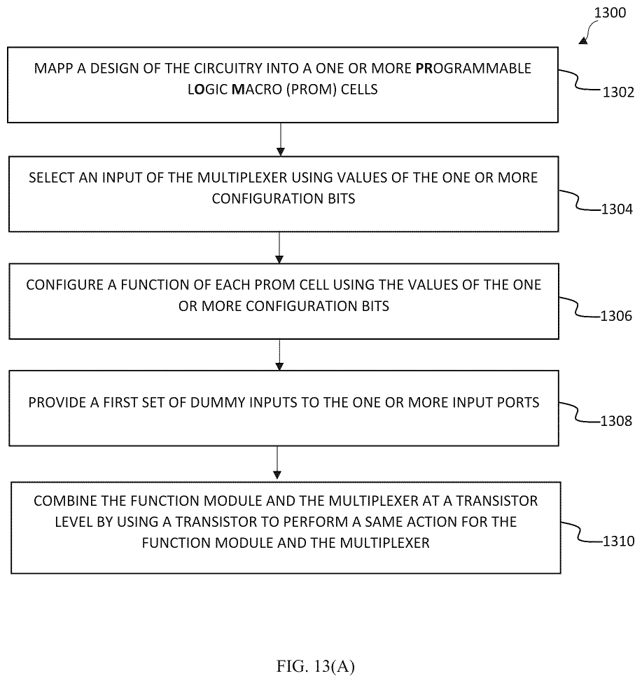

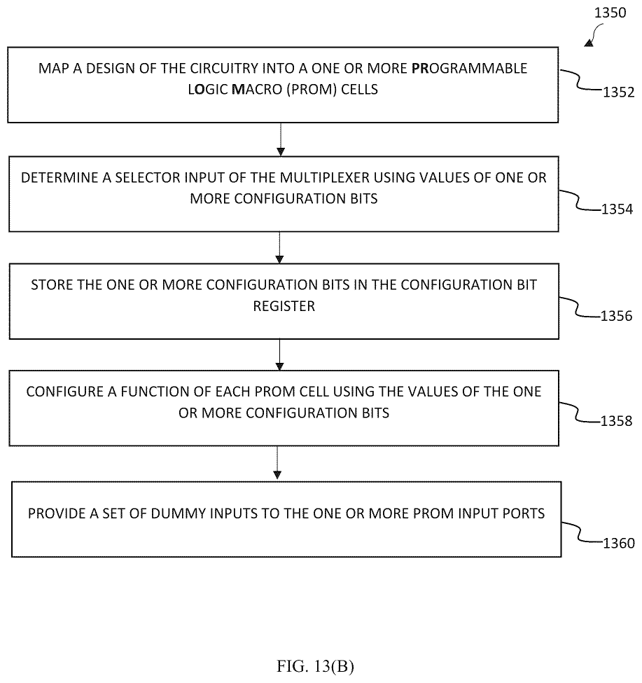

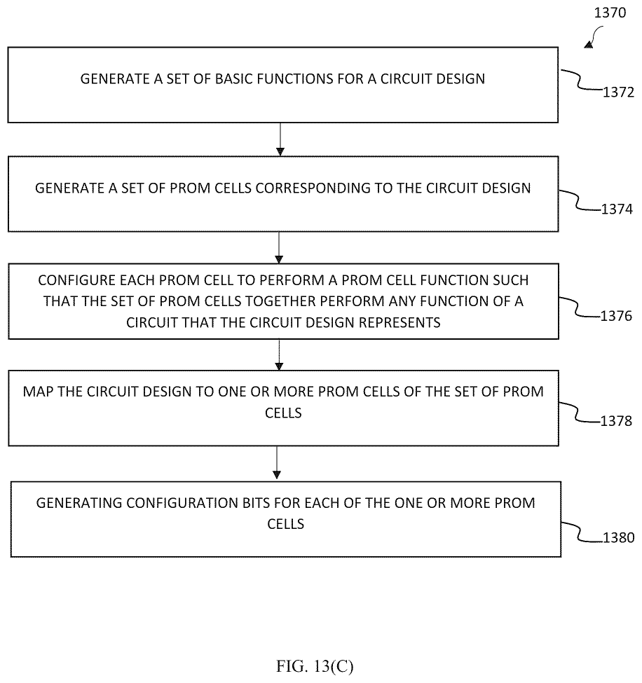

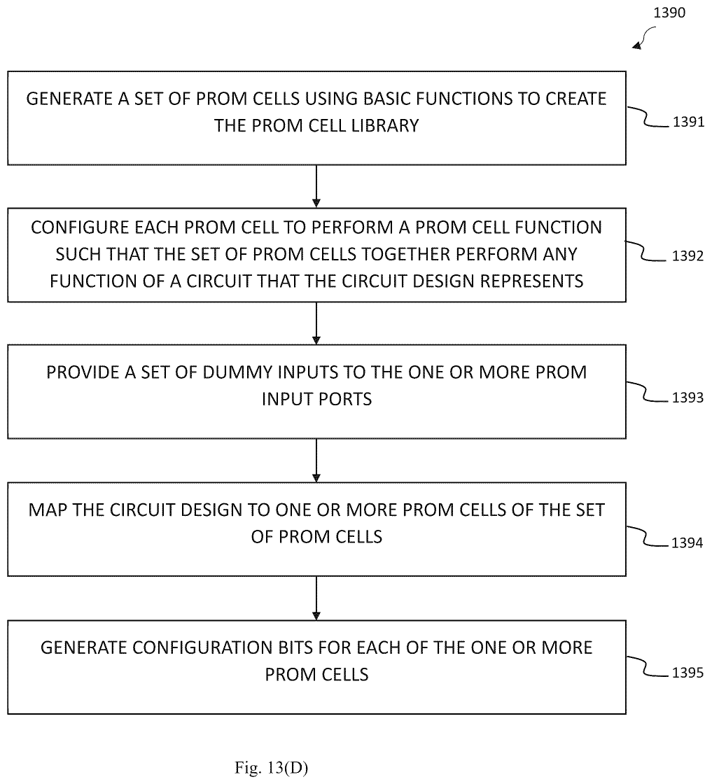

Referring now to FIG. 13(A), a flowchart is provided describing a method 1300 for designing a programmable circuitry in accordance with various embodiments, herein. In various embodiments, at step 1032, the method 1300 mapping a design of the circuitry into one or more PRogrammable lOgic Macro (PROM) cells. In various embodiments each PROM cell includes one or more input ports, one or more output ports, a function module, one or more configuration bits, and a multiplexer.

At step 1304, the method 1300 selects an input of the multiplexer using values of the one or more configuration bits. At step 1306, the method 1300 configures a function of each PROM cell using the values of the one or more configuration bits. In various embodiments, one or more control inputs of the multiplexer are electronically coupled to the function module and the multiplexer electronically couples an operation circuitry from the function module to an output port of the one or more output ports using the values of the one or more configuration bits. At step 1308, the method 1300 provides a first set of dummy inputs to the one or more input ports.

In various embodiments, the values of the one or more configuration bits to perform the function of the corresponding PROM cell and the first set of dummy inputs is unknown in a fabricating process of the circuitry.

In various embodiments, the function module provides an encryption function comprising any of AES, SHA-256 and Hash using the values of the one or more configuration bits. In various embodiments, at step 1310, the method 1300 combines the function module and the multiplexer at a transistor level by using a transistor to perform a same action for the function module and the multiplexer. In various embodiments, the method 1300 may eliminate a plurality of duplicate transistors between the function module and the multiplexer. In various embodiments, the method 1300 may use one or more control transistors configured to control the transistor to perform the same action for any of the function module and the multiplexer at the transistor level.

Referring now to FIG. 13(B) a flowchart illustrating method 1350 is provided in accordance with various embodiments of the present disclosure. In various embodiments, method 1350 provides designing a programmable circuitry. In various embodiments, at step 1352, the method 1350 maps a design of the programmable circuitry into one or more PRogrammable lOgic Macro (PROM) cells. In various embodiments, each PROM cell may include one or more PROM input ports, one or more PROM output ports, a function module, a configuration bit register, and a multiplexer, as for example previously described, for example with respect to FIG. 1.

In various embodiments, at step 1354, the method 1350 determines a selector input of the multiplexer using values of one or more configuration bits. At step 1356, the method 1350 stores the one or more configuration bits in the configuration bit register.

In various embodiments, at step 1358, the method 1350 configures a function of each PROM cell using the values of the one or more configuration bits. At step 1360, the method 1350 provides a set of dummy inputs to the one or more PROM input ports. In various embodiments, the set of dummy inputs is unknown in a fabricating process of the programmable circuitry and obfuscates the design of the circuitry. In various embodiments, the values of the one or more configuration bits determine a function of the corresponding PROM cell performed on the PROM inputs and the PROM output regardless of the set of dummy inputs.

In various embodiments, the one or more data inputs of the multiplexer are electronically coupled to the function module. In various embodiments, the multiplexer electronically couples an operation circuitry from the function module to a PROM output port of the one or more PROM output ports using the values of the one or more configuration bits.

In various embodiments, the method 1350 may combine the function module and the multiplexer at a transistor level by using a transistor to perform a common action of the function module and the multiplexer. In various embodiments, the method 1350 may eliminate a plurality of duplicate transistors between the function module and the multiplexer to reduce an area consumption in the programmable circuitry. In various embodiments, the method 1350 may optimize the area consumption by combining any common actions of the function module and the multiplexer at a transistor level.

In various embodiments, the method 1350 may customize each PROM cell by varying at least one of a PROM input size, a PROM output size, or the function of the corresponding PROM cell using the one or more configuration bits. In various embodiments, the method may customize any PROM inputs and PROM outputs and relationship between the PROM outputs and PROM inputs using the one or more configuration bits, wherein the customization comprises varying any of the PROM input size, PROM output size, and the function of the PROM cell.

In various embodiments, the method 1350 may incorporate the PROM cell in a netlist design of the programmable circuitry. In various embodiments, the method 1350 may vary at least one of a number of the one or more PROM input ports, a number of the one or more PROM output ports, the one or more configuration bits, or the set of dummy inputs.

In various embodiments, the method 1350 may randomize one or more interconnections in the programmable circuitry using at least one of the one or more configuration bits, or the set of dummy inputs. In various embodiments, the method may randomize one or more interconnections in the programmable circuitry using at least one of the PROM input ports, the PROM output ports, the one or more configuration bits, or the set of dummy inputs.

In various embodiments, the method 1350 may share the one or more configuration bits among function modules of the one or more PROM cells. In various embodiments, the method may share the one or more configuration bits among the one or more function modules of a PROM cell of the one or more PROM cells, wherein each PROM cell comprises one or more functions. In various embodiments, the method 1350 may overlap functions among the function modules corresponding to the one or more PROM cells.

Referring now to FIG. 13(C), a schematic diagram illustrating a method 1370 is provided in accordance with various embodiments of the present disclosure. In various embodiments, at step 1372, the method 1370 generates a set of basic functions for a circuit design. At step 1374, the method 1370 may generate a set of PROM cells corresponding to the circuit design. At step 1376, the method 1370 may configure each PROM cell to perform a PROM cell function such that the set of PROM cells together perform any function of a circuit that the circuit design represents.

In various embodiments, at step 1378, the method 1370 maps the circuit design to one or more PROM cells of the set of PROM cells. At step 1380, the method 1370 may generate configuration bits for each of the one or more PROM cells, wherein the configuration bits program the PROM cell to perform the PROM cell function, such that a set of programmed PROM cells perform a specific function of the circuit.

In various embodiments, every PROM cell is configured to be programmed to be able to perform every function in the set of basic functions. In various embodiments, each PROM cell is configured to receive M inputs and S configuration bits, and generate an output, wherein M and S are integer numbers, and the PROM cell is configured to perform 2^{S} unique functions using the S configuration bits.

In various embodiments, the PROM cell may include a function module and the function module includes 2^{S} sub-function modules, wherein each sub-function module is provided with the M inputs and generates a corresponding sub-function output.

In various embodiments, the PROM cell may further include a 2^{S}:1 multiplexer, configured to receive sub-function outputs of each of the 2S sub-function modules and generate the output of the PROM cell using the S configuration bits. In various embodiments, the PROM cell further includes an S-bit register configured to store the S configuration bits, wherein the S-bit shift register is electronically coupled to a selection input of the 2^{S}:1 multiplexer. In various embodiments, the method 1370 further includes incorporating each PROM cell in a netlist design of the circuit. In various embodiments, a subset of the M inputs are dummy inputs.

In various embodiments, the method 1370 further includes obfuscating the circuit design. In various embodiments, the obfuscation includes providing a fabrication specification for fabricating the PROM cells of the circuit design and fabrication or architectural requirements for each PROM cell, and hiding the dummy inputs in the fabrication specification.

In various embodiments, a PROM cell is provided. The PROM cell may include a function module, for example function module 160 with reference to FIG. 1(b). In various embodiments, the function module may include M inputs, where M is an integer, and 2^{S} operation circuitry, for example the operation circuitries 162. S is an integer number and each operation circuitry may include electronic components configured to perform a function on an input of the operation circuitry and generate an output of the operation circuitry. In various embodiments, each operation circuitry includes an Application Specific Integrated Circuit (ASIC) for performing its corresponding function. In various embodiments, each operation circuitry includes basic logic components such as any of AND gate, OR gate, and/or XOR gate, etc. to perform the corresponding function. In various embodiments, the operation circuitry includes a look up table to perform the corresponding function. In various embodiments, the operation circuitry includes a Field Programmable Gate Array (FPGA) to perform the corresponding function.

In various embodiments, the PROM cell includes a 2^{S}:1 multiplexer, for example 2^{S}:1 multiplexer 158. The 2^{S}:1 multiplexer may be configured to receive sub-function outputs of each of the 2S sub-function modules and generate the output of the PROM cell.

In various embodiments, the PROM cell includes an S-bit register configured to store the S configuration bits. In various embodiments, the S-bit shift register is electronically coupled to a selection input of the 2S:1 multiplexer.

Referring now to FIG. 13(D), a flowchart illustrating a method 1390 is provided in accordance with various embodiments of the present disclosure. In various embodiments, at step 1391, the method 1390 generates a set of basic functions for a circuit design. At step 1392, the method 1390 may configure each PROM cell to perform a PROM cell function such that the set of PROM cells together perform any function of a circuit that the circuit design represents.

At step 1393, the method 1390 provides a set of dummy inputs to the one or more PROM input ports. In various embodiments, the set of dummy inputs is unknown in a fabricating process of the programmable circuitry and obfuscates the design of the circuitry. In various embodiments, the values of the one or more configuration bits determine a function of the corresponding PROM cell performed on the PROM inputs and the PROM output regardless of the set of dummy inputs.

In various embodiments, at step 1394, the method 1390 maps the circuit design to one or more PROM cells of the set of PROM cells. At step 1395, the method 1390 may generate configuration bits for each of the one or more PROM cells, wherein the configuration bits program the PROM cell to perform the PROM cell function, such that a set of programmed PROM cells perform a specific function of the circuit.

In various embodiments, every PROM cell is configured to be programmed to be able to perform every function in the set of basic functions. In various embodiments, each PROM cell is configured to receive M inputs and S configuration bits, and generate an output, wherein M and S are integer numbers, and the PROM cell is configured to perform 2^{S} unique functions using the S configuration bits.

In various embodiments, the PROM cell may include a function module and the function module includes 2^{S} sub-function modules, wherein each sub-function module is provided with the M inputs and generates a corresponding sub-function output.

In various embodiments, the PROM cell may further include a 2^{S}:1 multiplexer, configured to receive sub-function outputs of each of the 2^{S} sub-function modules and generate the output of the PROM cell using the S configuration bits. In various embodiments, the PROM cell further includes an S-bit register configured to store the S configuration bits, wherein the S-bit shift register is electronically coupled to a selection input of the 2^{S}:1 multiplexer. In various embodiments, the method 1300, the method 1350, the method 1370, and/or the method 1390 further includes incorporating each PROM cell in a netlist design of the circuit. In various embodiments, a subset of the M inputs are dummy inputs.

### Example Technical Implementation of Various Embodiments

Embodiments of the present disclosure may be implemented in various ways, including as computer program products that comprise articles of manufacture. Such computer program products may include one or more software components including, for example, software objects, methods, data structures, and/or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query, or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include a non-transitory computer-readable storage medium, storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid-state drive (SSD), solid state card (SSC), solid state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may also be implemented as methods, apparatus, systems, computing devices, computing entities, and/or the like. As such, embodiments of the present disclosure may take the form of a data structure, apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises a combination of computer program products and hardware performing certain steps or operations.

Embodiments of the present disclosure are described with reference to example operations, steps, processes, blocks, and/or the like. Thus, it should be understood that each operation, step, process, block, and/or the like may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some exemplary embodiments, retrieval, loading, and/or execution may be performed in parallel such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

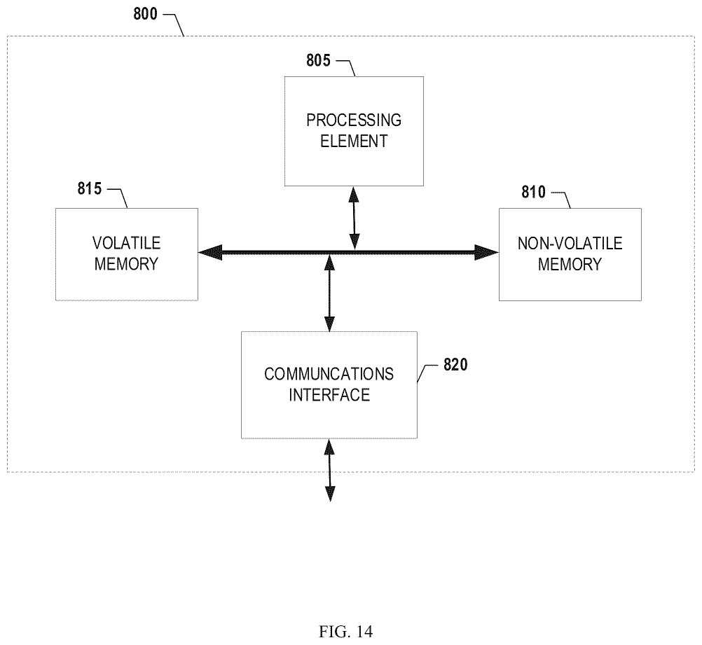

FIG. 14 provides a schematic of an exemplary apparatus 800 that may be used in accordance with various embodiments of the present disclosure. In particular, the apparatus 800 may be configured to perform various example operations described herein to provide for obfuscation, algebraic transformation, structural artifact removal, and/or interconnect structure transformation for security of integrated circuits. In some example embodiments, the apparatus 800 may be embodied by the hardware design process 100.

In general, the terms computing entity, entity, device, and/or similar words used herein interchangeably may refer to, for example, one or more computers, computing entities, desktop computers, mobile phones, tablets, phablets, notebooks, laptops, distributed systems, items/devices, terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

Although illustrated as a single computing entity, those of ordinary skill in the field should appreciate that the apparatus 800 shown in FIG. 14 may be embodied as a plurality of computing entities, tools, and/or the like operating collectively to perform one or more processes, methods, and/or steps. As just one non-limiting example, the apparatus 800 may comprise a plurality of individual data tools, each of which may perform specified tasks and/or processes.

Depending on the embodiment, the apparatus 800 may include one or more network and/or communications interfaces 820 for communicating with various computing entities, such as by communicating data, content, information, and/or similar terms used herein interchangeably that can be transmitted, received, operated on, processed, displayed, stored, and/or the like. Thus, in certain embodiments, the apparatus 800 may be configured to receive data from one or more data sources and/or devices, as well as receive data indicative of input, for example, from a device.

The networks used for communicating may include, but are not limited to, any one or a combination of different types of suitable communications networks such as, for example, cable networks, public networks (e.g., the Internet), private networks (e.g., frame-relay networks), wireless networks, cellular networks, telephone networks (e.g., a public switched telephone network), or any other suitable private and/or public networks. Further, the networks may have any suitable communication range associated therewith and may include, for example, global networks (e.g., the Internet), MANs, WANs, LANs, or PANs. In addition, the networks may include any type of medium over which network traffic may be carried including, but not limited to, coaxial cable, twisted-pair wire, optical fiber, a hybrid fiber coaxial (HFC) medium, microwave terrestrial transceivers, radio frequency communication mediums, satellite communication mediums, or any combination thereof, as well as a variety of network devices and computing platforms provided by network providers or other entities.

Accordingly, such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the apparatus 800 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), 5G New Radio (5G NR), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The apparatus 800 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

In addition, in various embodiments, the apparatus 800 includes or is in communication with one or more processing elements 805 (also referred to as processors, processing circuitry, and/or similar terms used herein interchangeably) that communicate with other elements within the apparatus 800 via a bus, for example, or network connection. As will be understood, the processing element 805 may be embodied in several different ways. For example, the processing element 805 may be embodied as one or more complex programmable logic devices (CPLDs), microprocessors, multi-core processors, coprocessing entities, application-specific instruction-set processors (ASIPs), and/or controllers. Further, the processing element 805 may be embodied as one or more other processing devices or circuitry. The term circuitry may refer to an entirely hardware embodiment or a combination of hardware and computer program products. Thus, the processing element 805 may be embodied as integrated circuits, application specific integrated circuits (ASICs), field programmable gate arrays (FPGAs), programmable logic arrays (PLAs), hardware accelerators, other circuitry, and/or the like.

As will therefore be understood, the processing element 805 may be configured for a particular use or configured to execute instructions stored in volatile or non-volatile media or otherwise accessible to the processing element 805. As such, whether configured by hardware, computer program products, or a combination thereof, the processing element 805 may be capable of performing steps or operations according to embodiments of the present disclosure when configured accordingly.

In various embodiments, the apparatus 800 may include or be in communication with non-volatile media (also referred to as non-volatile storage, memory, memory storage, memory circuitry, and/or similar terms used herein interchangeably). For instance, the non-volatile storage or memory may include one or more non-volatile storage or non-volatile memory media 810 such as hard disks, ROM, PROM, EPROM, EEPROM, flash memory, MMCs, SD memory cards, Memory Sticks, CBRAM, PRAM, FeRAM, RRAM, SONOS, racetrack memory, and/or the like. As will be recognized, the non-volatile storage or non-volatile memory media 810 may store files, databases, database instances, database management system entities, images, data, applications, programs, program modules, scripts, source code, object code, byte code, compiled code, interpreted code, machine code, executable instructions, and/or the like. The terms database, database instance, database management system entity, and/or similar terms used herein interchangeably and in a general sense refer to a structured or unstructured collection of information/data that is stored in a computer-readable storage medium.

In particular embodiments, the non-volatile memory media 810 may also be embodied as a data storage device or devices, as a separate database server or servers, or as a combination of data storage devices and separate database servers. Further, in some embodiments, the non-volatile memory media 810 may be embodied as a distributed repository such that some of the stored information/data is stored centrally in a location within the system and other information/data is stored in one or more remote locations. Alternatively, in some embodiments, the distributed repository may be distributed over a plurality of remote storage locations only. As already discussed, various embodiments contemplated herein use data storage in which some or all of the information/data required for various embodiments of the disclosure may be stored.

In various embodiments, the apparatus 800 may further include or be in communication with volatile media (also referred to as volatile storage, memory, memory storage, memory circuitry, and/or similar terms used herein interchangeably). For instance, the volatile storage or memory may also include one or more volatile storage or volatile memory media 815 as described above, such as RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like.

As will be recognized, the volatile storage or volatile memory media 815 may be used to store at least portions of the databases, database instances, database management system entities, data, images, applications, programs, program modules, scripts, source code, object code, byte code, compiled code, interpreted code, machine code, executable instructions, and/or the like being executed by, for example, the processing element 805. Thus, the databases, database instances, database management system entities, data, images, applications, programs, program modules, scripts, source code, object code, byte code, compiled code, interpreted code, machine code, executable instructions, and/or the like may be used to control certain aspects of the operation of the apparatus 800 with the assistance of the processing element 805 and operating system.

As will be appreciated, one or more of the computing entity's components may be located remotely from other computing entity components, such as in a distributed system. Furthermore, one or more of the components may be aggregated, and additional components performing functions described herein may be included in the apparatus 800. Thus, the apparatus 800 can be adapted to accommodate a variety of needs and circumstances.

In various embodiments, the computing entity may perform any of the steps of the various methods described above.

### CONCLUSION

Many modifications and other embodiments of the disclosures set forth herein will come to mind to one skilled in the art to which these disclosures pertain having the benefit of the teachings presented in the foregoing descriptions and the associated drawings. Therefore, it is to be understood that the disclosures are not to be limited to the specific embodiments disclosed and that modifications and other embodiments are intended to be included within the scope of the appended claims. Although specific terms are employed herein, they are used in a generic and descriptive sense only and not for purposes of limitation.

1. A method for designing a programmable circuitry, the method comprising:
mapping a design of the programmable circuitry into one or more PRogrammable lOgic Macro (PROM) cells, wherein each PROM cell comprises one or more PROM input ports, one or more PROM output ports, a function module, a configuration bit register, and a multiplexer;
determining a selector input of the multiplexer using values of one or more configuration bits;
storing the one or more configuration bits in the configuration bit register;
configuring a function of each PROM cell using the values of the one or more configuration bits; and
providing a set of dummy inputs to the one or more PROM input ports, wherein (a) the set of dummy inputs is unknown in a fabricating process of the programmable circuitry and obfuscates the design of the programmable circuitry and (b) the values of the one or more configuration bits determine a function of the corresponding PROM cell performed on PROM inputs and PROM output regardless of the set of dummy inputs.

2. The method of claim 1, wherein one or more data inputs of the multiplexer are electronically coupled to the function module and the multiplexer electronically couples an operation circuitry from the function module to a PROM output port of the one or more PROM output ports using the values of the one or more configuration bits.

3. The method of claim 1 further comprising:
combining the function module and the multiplexer at a transistor level by using a transistor to perform a common action of the function module and the multiplexer;
eliminating a plurality of duplicate transistors between the function module and the multiplexer to reduce an area consumption in the programmable circuitry; and
optimizing the area consumption by combining any common actions of the function module and the multiplexer at a transistor level.

4. The method of claim 1 further comprising customizing each PROM cell by varying at least one of a PROM input size, a PROM output size, or the function of the corresponding PROM cell using the one or more configuration bits.

5. The method of claim 1 further comprising incorporating the one or more PROM cells in a netlist design of the programmable circuitry.

6. The method of claim 1 further comprising varying at least one of a number of the one or more PROM input ports, a number of the one or more PROM output ports, the one or more configuration bits, or the set of dummy inputs.

7. The method of claim 1 further comprising randomizing one or more interconnections in the programmable circuitry using at least one of the one or more configuration bits, or the set of dummy inputs.

8. The method of claim 1 further comprising sharing the one or more configuration bits among function modules of the one or more PROM cells.

9. The method of claim 8 further comprising overlapping functions among the function modules of the one or more PROM cells.

10. A method comprising:
generating a set of basic functions for a circuit design;
generating a set of PRogrammable lOgic Macro (PROM) cells corresponding to the circuit design;
configuring each PROM cell to perform a PROM cell function such that the set of PROM cells together perform any function of a circuit that the circuit design represents;
mapping the circuit design to one or more PROM cells of the set of PROM cells; and
generating configuration bits for each of the one or more PROM cells, wherein the configuration bits program the corresponding PROM cell to perform the corresponding PROM cell function, such that a set of programmed PROM cells perform a specific function of the circuit.

11. The method of claim 10, wherein every PROM cell is configured to be programmed to perform any function in the set of basic functions.

12. The method of claim 11, wherein each PROM cell is configured to receive M inputs and S configuration bits, and generate an output, wherein M and S are integer numbers and the corresponding PROM cell is configured to perform 2^{S} unique functions using the S configuration bits.

13. The method of claim 12, wherein the corresponding PROM cell comprises a function module and the function module comprises 2^{S} sub-function modules, wherein each sub-function module is provided with the M inputs and generates a corresponding sub-function output.

14. The method of claim 13, wherein the corresponding PROM cell further comprises a 2^{S}:1 multiplexer, configured to receive sub-function outputs of each of the 2^{S} sub-function modules and generate the output of the corresponding PROM cell using the S configuration bits.

15. The method of claim 14, wherein the corresponding PROM cell further comprises an S-bit register configured to store the S configuration bits, wherein the S-bit shift register is electronically coupled to a selection input of the 2^{S}:1 multiplexer.

16. The method of claim 15, further comprising incorporating each PROM cell in a netlist design of the circuit.

17. The method of claim 16, wherein a subset of the M inputs are dummy inputs.

18. The method of claim 17, further comprising obfuscating the circuit design, wherein the obfuscation comprises:
providing a fabrication specification for fabricating the set of PROM cells of the circuit design and fabrication or architectural requirements for each PROM cell; and
hiding the dummy inputs in the fabrication specification.

19. A PRogrammable lOgic Macro (PROM) cell comprising:
a function module comprising:
M inputs, where M is an integer;
2^{S} operation circuitry, wherein S is an integer number and each operation circuitry comprises electronic components configured to perform a function on an input of the operation circuitry and generate an output of the operation circuitry; and
a 2^{S}:1 multiplexer, configured to receive sub-function outputs of each of the 2^{S} sub-function modules and generate the output of the corresponding PROM cell.

20. The PROM cell of claim 19 comprising an S-bit register configured to store the S configuration bits, wherein the S-bit shift register is electronically coupled to a selection input of the 2^{S}:1 multiplexer.
